(19) United States
(12) Patent Application Publication
(10) Pub. No.: US 2014/0043585 A1
(43) Pub. Date: Feb. 13, 2014

(54) Method for promoting adhesion of hard coat to optical substrate

(71) Applicant: Brian C. Wilson, Mentor, OH (US)

(72) Inventor: Brian C. Wilson, Mentor, OH (US)

(21) Appl. No.: 13/568,938

(22) Filed: Aug. 7, 2012

(51) Int. Cl. B32B 9/00; G02C 7/02; C23C 14/34; B05D 5/06; C23C 14/30

(52) U.S. Cl. 351/159.57; 427/162; 427/596; 428/446; 428/336; 204/192.11

(57) ABSTRACT

A method for adhering a hard coat layer to an optical substrate is provided, includes providing an optical substrate, depositing a silicon oxide film on the optical substrate using vacuum deposition, applying a hard coat layer to the silicon oxide film for forming a hard-coated optical substrate, and curing the hard coat layer to form the hard-coated optical substrate. A hard-coated optical substrate includes an optical substrate, a hard coat layer, and a silicon oxide film intermediate the optical substrate and hard coat layer.

### BACKGROUND

The exemplary embodiment relates to a multilayer optical structure and method of forming the structure and finds particular application in adhering an optically transparent hard coat to an optical polymeric substrate.

Hard coat layers have been applied to a variety of different substrates to increase abrasion and chemical resistance and to avoid scratching upon handling. A typical application of hard coating includes optical hard coating. A hard coat is provided to optical substrates, such as those used in liquid crystal displays, plasma displays, mobile phone displays, and glasses, to impart further scratch resistance and durability, without compromising optical clarity.

There are many factors to consider when choosing an optical substrate. These factors include the ease of manufacture of the optical substrate through existing processes, such as injection molding, as well as desired performance characteristics, such as high transparency (80%+) in the visible range (400-800 nm wavelength) of light, high heat resistance, and refractive index stability. However, while some optical substrates may be desired for having many or all of these qualities, the optical substrate may not be able to be effectively hard-coated to improve inherent scratch resistance and durability. Hard coating layers must be sufficiently adhered to the optical substrate in order to impart these improved characteristics.

Cyclic olefin polymer substrates, such as ZEONEX™ and ZEONOR™ (available from Zeon Chemicals, Japan), possess many desired qualities for an optical substrate. They are polymers with a glass-like refractive index, low birefringence, and higher purity than traditional optical compounds such as polymethyl methacrylate (PMMA) and polycarbonates, e.g. CR-39 allyl diglycol carbonate, used in eye glasses and like applications. However, cyclic olefin substrates are not particularly amenable to hard coating. Traditional hard coating procedures, such as dip coating, spray coating, flow coating, and spin coating, result in hard coat layers that do not adhere well to cyclic olefin polymer substrates, and peel off the optical substrates in standard tape tests or through manual abrasion.

An improved method for hard coating is desired that promotes adhesion of a hard coat layer to an optical substrate.

### BRIEF DESCRIPTION

In one aspect of the exemplary embodiment, a method for adhering a hard coat layer to an optical substrate is provided. Also provided is a hard-coated optical substrate.

In one embodiment, a method for adhering a hard coat layer to an optical substrate comprises providing an optical substrate, depositing a silicon oxide film on the optical substrate using vacuum deposition, applying a hard coat layer to the silicon oxide film for forming a hard-coated optical substrate, and curing the hard coat layer to form a hard-coated optical substrate.

In another embodiment, a hard-coated optical substrate comprises an optical substrate, a hard coat layer, and a silicon oxide film on the optical substrate which spaces the hard coat layer from the optical substrate.

### BRIEF DESCRIPTION OF THE DRAWINGS

FIG. 1 is a flow diagram of a process for adhering a hard coat layer to an optical substrate;

FIG. 2 is a schematic view of an optical substrate with optional intermediate layers and a silicon oxide film formed after vacuum deposition; and

FIG. 3 is a schematic view of a hard-coated optical substrate with a silicon oxide film, an applied hard coat layer, and optional liquid coat layers.

### DETAILED DESCRIPTION

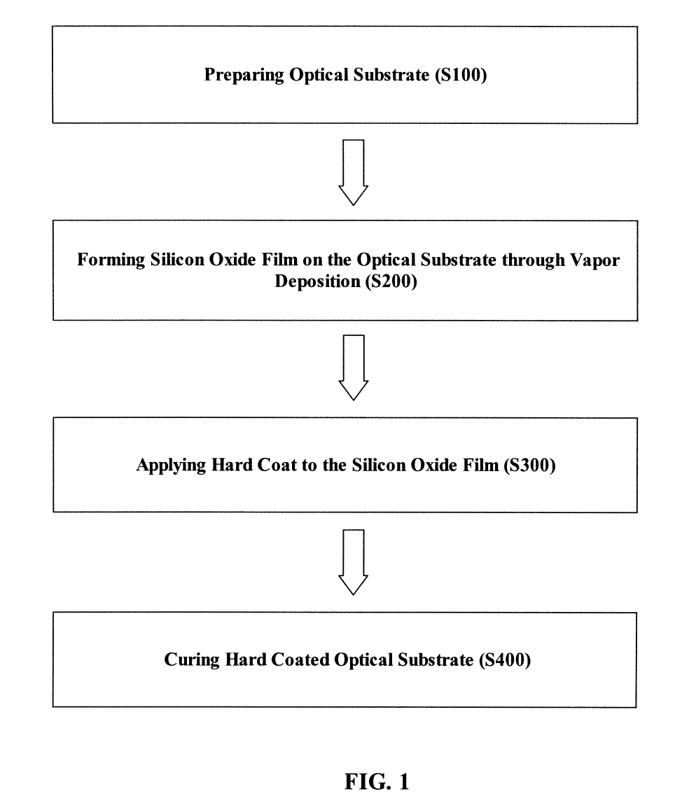

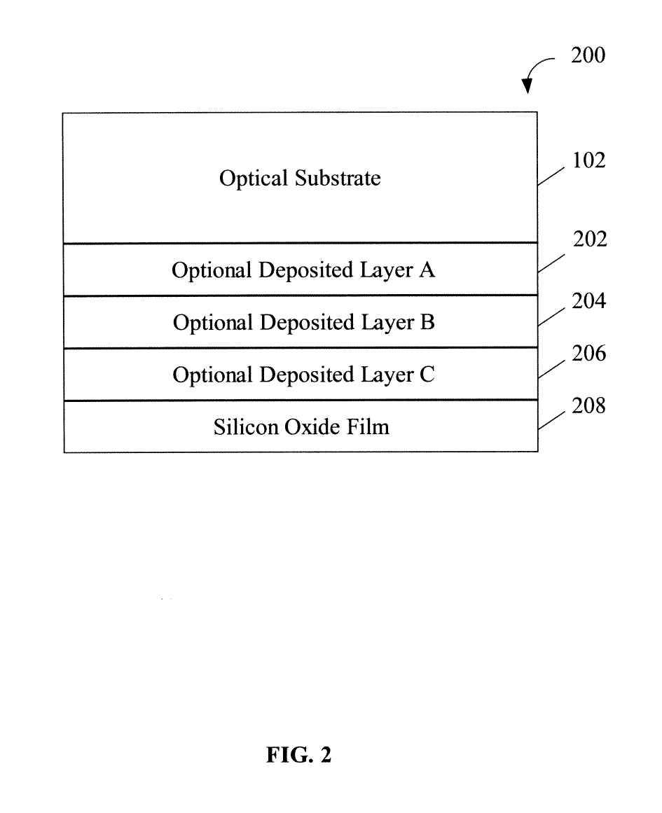

With reference to FIG. 1, a method for forming a hard-coated optical substrate is shown. An optical substrate is provided (S100). The optical substrate may be prepared by any suitable method and may include molding (e.g., injection molding), shaping, grinding, and/or otherwise forming a solid substrate having a suitable thickness for the desired application, such as at least one lens of a pair of glasses. The optical substrate may undergo one or more preparation steps, which may include ultrasonically cleaning the optical substrate 102 (FIG. 2).

The exemplary optical substrate 102 is formed of an optically transmissive polymer and has a transparency (transmission) between 80-100% in the 400 nm-700 nm (visible light) region of the electromagnetic spectrum, such as at least 85% or at least 90% transmission. The optical substrate material may be selected from a wide range of polymer materials, including organic polymers such as polyhydrocarbons, polyoxyhydrocarbons, polysulfohydrocarbons, and fluorocarbon and flurohydrocarbon materials. Representative optical organic polymers include polyesters, such as poly(ethylene terephthalate), poly(butylene terephthalate), such as optical polyesters sold under the tradenames OKP4 and OKP4-HT, available from Osaka Gas Chemicals Corporation, Japan. Other optical organic polymers include polyacrylates and methacrylates, such as poly(methyl methacrylate) (PMMA), poly(methacrylate), and poly(ethyl acrylate), copolymers such as poly(methyl methacrylate-coethyl acrylate) and polycarbonates, and flurocarbon polymers such as TEFLON™.

Other specific optical organic polymers that can be used as the optical substrate 102 include allyl diglycol carbonate resins, such as CR39™, marketed by PPG Industries, Pittsburgh, and cyclic olefin polymer substrates, which can be produced by chain copolymerization of cyclic monomers such as 8,9,10-trinorborn-2-ene (norbornene) or tetracyclododecene with an alkene, such as ethene, or by ring-opening metathesis polymerization of various cyclic monomers followed by hydrogenation. Examples of cyclic olefin polymer substrates include ZEONEX™ and ZEONOR™ cyclic olefin polymer resins marketed by Zeon Corporation, Japan, which are formed by the latter process. Exemplary cyclic olefin polymer resins marketed by Zeon Corporation are described in U.S. Pat. Nos. 6,486,264; 6,511,756; 6,908,970; and 7,084,222, the disclosures of which are incorporated herein by reference. Particular ZEONEX™ substrate materials that are useful in the exemplary method for adhering a hard coat layer to an optical substrate include ZEONEX 350R, 330R, 480R, E48R, F52R, and combinations thereof. Other useful cyclic olefin polymers which may be used for the substrate are described in U.S. Pub. No. 2011/0033634, the disclosure of which is incorporated herein by reference in its entirety.

The exemplary optical substrate is at least 90 wt. %, or at least 95 wt. % and up to 100 wt. % cyclic olefin polymers. It can be at least 0.5 mm or at least 1 mm in thickness, and can be up to 1 cm, or up to 0.5 cm in thickness and can be curved in the shape of a lens of a pair of prescription or non-prescription spectacles.

In a subsequent step S200, a silicon oxide film 208 is formed on the optical substrate 102. In the exemplary embodiment, this is achieved through vacuum deposition, although other deposition processes, such as chemical and physical vapor deposition are also contemplated. The silicon oxide film 208 may be substantially pure silicon oxide, e.g., silicon and oxygen together comprise at least 95 wt. % or at least 98 wt. %, or at least 99 wt. %, or at least 99.5 wt. %, and up to 100 wt. % of the silicon oxide film 208. The film 208 can be composed of silicon monoxide (SiO), silicon dioxide (SiO₂), or a non-stoichiometric mixture of silicon and oxygen. The silicon oxide film 208 may consist of a single uniform layer of under 50 nm, e.g., approximately 1-20 nanometers in thickness. The silicon oxide film 208 may directly contact one or both surfaces of the optical substrate 102. In other embodiments the silicon oxide film may be spaced from the optical substrate by one or more intermediate layers. For example, as shown in FIG. 2, the silicon oxide film may optionally be deposited on top of one or more intermediate layers 202, 204, 206, which may be formed of silicon oxide or other material, provided that the outermost layer, facing the exposed air prior to deposition of the hard coat layer, is the silicon oxide film 208. Other layers 202, 204, 206, may include a broadband anti-reflective coating, a beam-splitter coating, a mirror coating, or combination thereof, which are applied, for example, through vacuum deposition or other deposition process, onto the optical substrate 102, in any order, before deposition of the silicon oxide film 208.

To achieve good adhesion of a hard coating layer 302 to the optical substrate 102, the silicon oxide film 208 may be deposited in a single uniform layer of under 100 nm, or up to 10 nanometers, such as approximately 1-3 nanometers in thickness, onto the optical substrate 102. While other layers 202, 204, 206 may be deposited on the optical substrate 102 before the silicon oxide film 208, in one embodiment, there are no intermediate layers. Uniform deposition of the silicon oxide film 208 may by controlled by quartz crystal monitoring. During quartz crystal monitoring, the optical substrate 102 with silicon oxide layer 208 oscillate at a specific frequency and communicate with a programmable logic controller to control whether a subsequent layer of silicon oxide should be deposited onto the optical substrate 102 to achieve a desired thickness of the silicon oxide film 208.

Vacuum deposition of the silicon oxide film 208 may be performed by a variety of processes, such as general physical vapor deposition (“PVD”), chemical vapor deposition (“CVD”), and electron beam assisted vapor deposition (“EBVD”). In PVD, a vaporized form of the silicon oxide film 208 is condensed onto the optical substrate 102. This is a purely physically process involving high temperature vacuum evaporation with subsequent condensation. A variant of this procedure involves plasma sputter bombardment of silicon oxide onto the optical substrate 102. In CVD, the optical substrate 102 is exposed to one or more volatile precursors, which react and/or decompose on the optical substrate 102 surface to produce the silicon oxide film 208. Volatile by-products are frequently produced by this process, which are removed by gas flow through a vacuum deposition chamber.

EBVD is a method of PVD wherein a coating film, such as silicon oxide film 208, is deposited onto the optical substrate 102 through the use of an electron beam. The electron beam physically vaporizes a dielectric material or materials, such as TiO₂, AlO₂, MgF₂, Si, SiOₓ, where x can be 1 (SiO), 2 (SiO₂), or a mixed oxide, to deposit a film upon the optical substrate 102. Which dielectric material(s) is/are used in EBVD depends on the desired properties of the deposited film, e.g., anti-reflective. For example, MgF₂ is a common anti-reflective coating for glass substrates. In the exemplary embodiment, the silicon oxide film 208 is deposited by EBVD. SiOₓ layers can also be formed by electron beam assisted chemical vapor deposition through dissociation of SiH₄ and N₂O.

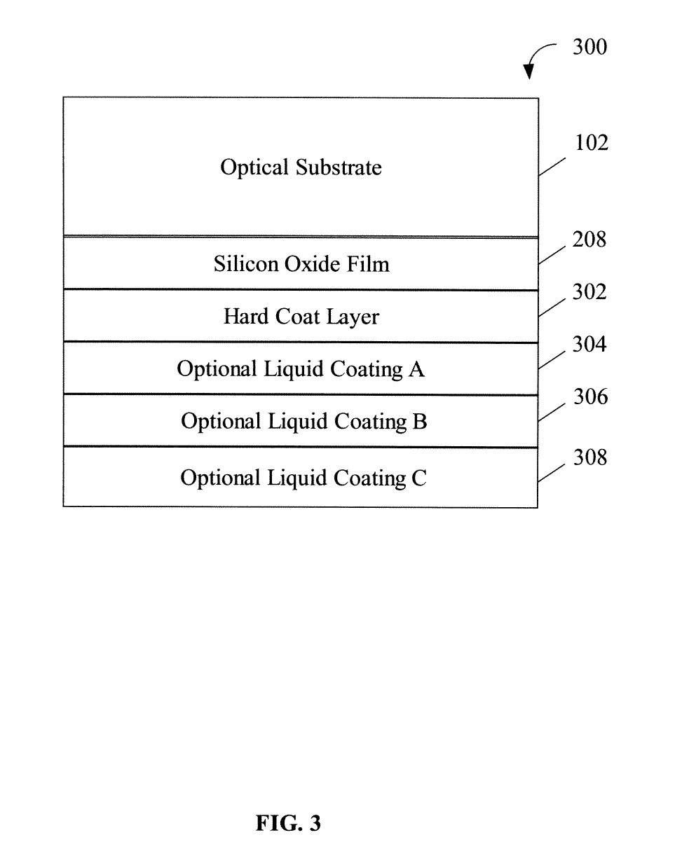

In a further step S300, a hard coat layer 302 is applied to the silicon oxide film 208, e.g., as a liquid or gel having a viscosity of less than 3000 cP, for forming a hard-coated optical substrate 300 (FIG. 3). The hard coat layer is applied directly to the silicon oxide film, i.e., with no intervening layers, so that the cured hard coat layer 302 is in contiguous contact with the silicon oxide layer. The hard coat layer 302, when cured, can be any suitable cured polymer resin, such as a polysiloxane or polyurethane coating, which is used to increase durability and scratch resistance of the optical substrate 102. Polysiloxane or polyurethane coatings exhibit excellent chemical resistance and are optically transmissive. They are also excellent base coatings which can be coupled with additional optical coatings, as they increase the durability of any additional coatings applied to them. The hard coat layer 302 is typically applied in liquid form at a thickness of 3-5 μm as one or more layers, and is completely transparent (e.g., at least 95% or at least 98% transmissive). The exemplary hard coat layer 302 is applied in liquid or gel form followed by curing, rather than vacuum deposition applied layers (as in S200) due to increased abrasion resistance and chemical resistance. The resulting hard coat layer has a thickness, for example, of at least 0.1 μm and can be up to 1 mm, such as up to 10 μm, e.g., 1-5 μm.

Exemplary polysiloxane-based coating compositions useful herein are disclosed in U.S. Pat. Nos. 3,986,997; 4,027,073; 4,177,315; 4,355,135; 5,069,942; and 8,080,311, the disclosures of which are incorporated herein by reference. Other coatings useful herein are CRYSTALCOAT™ polysiloxane or polyurethane hard coatings marketed by SDC Technologies, Irvine, Calif. Exemplary hard coatings marketed by SDC Technologies are described in U.S. Pat. Nos. 6,342,097; 7,014,918; 7,105,598; and 7,972,656, the disclosures of which are incorporated herein by reference. Particular CRYSTALCOAT™ hard coatings that are useful in the exemplary method for adhering a hard coat layer to an optical substrate include PF-2500, PR-700, MP-101, and combinations thereof.

An example curable polysiloxane composition for forming the hard coat layer 302 includes from 5-90 wt. % polysiloxane and from 10-95 wt. % diluent. Example diluents include organic diluents such as alcohols, e.g., methanol, ethanol, and isopropanol, and aqueous diluents, such as water. By way of example, the curable polysiloxane composition can have the following chemical characteristics:

TABLE I

| Characteristic | Typical Values |
|---|---|
| % Solids | 31-33 |
| Viscosity at 25° C. | <10.0 cps |
| Specific Gravity | 1.01 G/ML |
| ph | 4.4-5.2 |
| % Water | 12-14 |
| % Methanol | 30-32 |
| % Isopropanol | 20-22 |
| % Acetic Acid | 3-4 |
| Chemical Formula | [R₂SiO]ₙ |

Where R can be an alkyl group, for example a C1-C18 linear, branched and/or cyclic alkyl group, such as methyl, and n is at least 100, or at least 500, or at least 1000 (in the resulting cured hard coat). However, it will be appreciated that other polysiloxanes, polyesters, and mixtures thereof are also contemplated.

The curable polysiloxane (or polyester) coating composition for forming the hard coat layer 302 may be applied to the silicon oxide film 208 through dip coating, spray coating, flow coating, or spin coating. Dip coating is one specific method of applying the hard coat layer 302. In dip coating, the optical substrate 102 is submerged in the hard coating liquid composition (lacquer) and is then retracted at a specific withdrawal rate to maintain coating thickness and to minimize any “runs” or “drips” that may occur during extraction. For the polysiloxane hard coat 302, dip coating is performed with a withdrawal rate of approximately 10 inches/minute (4.2 mm/second).

In spray coating, optical substrates are sprayed similar to paint with a lacquer resin on one surface only. The optical substrates are suspended and rotated through in-line systems in front of spraying mechanisms.

In flowing coating, large amounts of optical substrate (normally on the order of 1 meter by 2 meters or larger) roll down a coating line via a conveyor and are subjected to a continuously cascading steam of hard coat lacquer resin.

In spin coating, an optical substrate is placed on a rounded surface perpendicular to the ground and a set amount of lacquer resin is injected on to the surface of the substrate. The optical substrate is then spun at a pre-determined rate of speed and the excess lacquer resin is “wicked” away through means of centrifugal force.

In a further step S400, the hard-coated optical substrate 300 undergoes a curing process. This may be achieved through UV light and/or thermal curing methods. Room temperature curing polysiloxanes are also available. UV curing occurs within a UV chamber where the substrate rapidly cures when exposed to high intensity UV light. During the exposure to UV light, solvents contained in the coating composition are evaporated from the layer 302 of hard-coated optical substrate 300, and the substrate 300 hardens. Thermal curing is a suitable curing process for the polysiloxane hard coat. In thermal curing, heat is used over time to evaporate solvents from the applied lacquer resin and form a harder substrate 300 that is more adverse to abrasion. The curing time and temperature are correlated to the thermal expansion and the melting point of the specific material being used. For an example polysiloxane hard coat, the polymer is dried under ambient conditions for 30 minutes and cured in an oven at approximately 82° C. (180° F.) for 4 hours. The cured hard coat layer 302 may have a thickness of up to 100 μm, e.g., be at least 3 μm in thickness.

The hard-coated optical substrate 300 may optionally include further coating layers 304, 306, 308 (FIG. 3). These coating layers 304, 306, 308 may include a hydrophobic over-coating, chemical resistant hard coating, anti-fog, or anti-static coating. These may be applied through dip, spray, spin, or flow coating of suitable liquid compositions after the hard coat layer 302 has been applied, before or after curing of the hard coat layer. Vapor deposition techniques may also be employed in other embodiments.

In one example embodiment, the substrate is formed of a cyclic olefin polymer, such as ZEONEX and/or ZEONOR. Such optical polymers are not normally amenable to hard coating through traditional dip, spray, spin, or flow liquid coating processes. Therefore, these optical polymers do not have an established liquid hard coat or known curing conditions. When prepared ZEONEX/ZEONOR optical substrates 102 are subjected to vapor deposition to produce a silicon oxide film 208 on the substrates, along with addition of a polysiloxane liquid hard coat 302 to the silicon oxide film 208, and subsequent curing S400 under conditions suited to the selected polysiloxane hard coat, these polymers exhibit an enhanced durability and scratch resistance which these liquid-applied hard coats can achieve.

In adhesion tape tests performed on polysiloxane hard coat to ZEONEX/ZEONOR substrates, a significant increase in adhesion of the polysiloxane hard coat to ZEONEX/ZEONOR is observed when a silicon oxide layer is interposed. It is expected that Tabor Abrasion ratings will suggest enhanced durability and scratch resistance of the underlying substrate, allowing for more widespread commercial use of these substrates in the optical display, mobile display, and glasses technology fields.

It will be appreciated that variants of the above-disclosed and other features and functions, or alternatives thereof, may be combined into many other different systems or applications. Various presently unforeseen or unanticipated alternatives, modifications, variations or improvements therein may be subsequently made by those skilled in the art which are also intended to be encompassed by the following claims.

What is claimed is:

1. A method for adhering a hard coat layer to an optical substrate, comprising:
(i) providing an optical substrate;
(ii) depositing a silicon oxide film on the optical substrate using vacuum deposition;
(iii) applying a hard coat layer on the silicon oxide film for forming a hard-coated optical substrate; and
(iv) curing the hard coat layer to form the hard-coated optical substrate.

2. The method of claim 1, wherein the depositing of the silicon oxide film is performed by electron beam vacuum deposition.

3. The method of claim 1, wherein the deposited silicon oxide film is up to 20 nm in thickness.

4. The method of claim 3, wherein the silicon oxide film is up to 3 nm in thickness.

5. The method of claim 1, wherein the deposited silicon oxide film is at least 1 nm in thickness.

6. The method of claim 1, further comprising depositing at least one intermediate layer intermediate the substrate and the silicon oxide film.

7. The method of claim 6, wherein the at least one intermediate layer is deposited by vacuum deposition.

8. The method of claim 6, wherein the at least one intermediate layer is at least one of an anti-reflective layer, a beam-splitting layer, and a mirror coating layer.

9. The method of claim 1, wherein the applying of the hard coat layer is performed by at least one of dip coating, spray coating, spin coating, and flow coating.

10. The method of claim 1, wherein the applying of the hard coat layer is performed by dip coating.

11. The method of claim 1, further comprising applying at least one additional liquid coating layer, the at least one additional layer being spaced from the silicon oxide film by the hard coat layer.

12. The method of claim 1, wherein the hard coat layer comprises at least one of a polysiloxane and a polyester.

13. The method of claim 12, wherein the hard coat layer comprises a polysiloxane.

14. The method of claim 1, wherein the cured hard coat layer has a thickness of up to 5 μm.

15. The method of claim 1, wherein the silicon oxide film is in direct contact with the hard coat layer of the hard-coated optical substrate.

16. The method of claim 1, wherein the optical substrate comprises a cyclic olefin polymer.

17. A hard-coated optical substrate comprising:
an optical substrate;
a hard coat layer; and
a silicon oxide film on the optical substrate which spaces the hard coat layer from the optical substrate.

18. The hard-coated optical substrate of claim 17, wherein the silicon oxide film is in direct contact with the hard coat layer.

19. The hard-coated optical substrate according to claim 17, wherein the silicon oxide film has a thickness of up to 20 nm.

20. The hard-coated optical substrate of claim 17, wherein the optical substrate comprises a cyclic olefin polymer.

21. The hard-coated optical substrate of claim 17, wherein the hard coat layer comprises a polysiloxane resin.

22. The hard-coated optical substrate of claim 17, wherein the hard coat layer has a thickness of up to 5 μm.

23. The hard-coated optical substrate of claim 17, further comprising at least one intermediate layer, the at least one intermediate layer spacing the optical substrate from the silicon oxide film.

24. The hard-coated optical substrate of claim 17, further comprising at least one additional layer, the at least one additional layer hard coat layer being spaced from the silicon oxide film and substrate by the hard coat layer.

25. A pair of spectacles including an optical lens comprising the hard-coated optical substrate of claim 17.
